(19) United States
(12) Patent Application Publication
(10) Pub. No.: US 2025/0293098 A1
(43) Pub. Date: Sep. 18, 2025

(54) SEMICONDUCTOR DEVICE AND METHOD OF MANUFACTURING THE SAME

(71) Applicant: Renesas Electronics Corporation, Tokyo (JP)

(72) Inventors: Tatsuya SASAKI, Tokyo (JP); Yuji ENARI, Tokyo (JP)

(21) Appl. No.: 19/052,025

(22) Filed: Feb. 12, 2025

(30) Foreign Application Priority Data
Mar. 13, 2024 (JP) 2024-038804

(51) Int. Cl. H01L 21/66; H01L 23/00; H01L 23/31; H10D 30/01; H10D 30/66

(52) U.S. Cl. CPC H01L 22/32; H01L 24/03; H01L 24/05; H10D 30/0297; H10D 30/668; H01L 23/3171; H01L 2224/03464; H01L 2224/04034; H01L 2224/04042; H01L 2224/05124; H01L 2224/05644; H01L 2224/05655; H01L 2224/05664

(57) ABSTRACT

A semiconductor device includes: a semiconductor substrate; an interlayer insulating film; a first and a second electrode pads; and a first and a second plating films. The semiconductor substrate has a first main surface and a second main surface opposite to the first main surface. The semiconductor substrate serves as an n-type drain region. The semiconductor substrate includes: an n-type source region; a p-type channel region adjacent to a side of the source region, the side being closer to the first main surface, and pn-bonded to the source region and the drain region; and a p-type well region and pn-bonded to the drain region. The interlayer insulating film is formed on the second main surface. The first electrode pad and the second electrode pad are formed on the interlayer insulating film and are electrically connected to the source region and the well region, respectively.

### CROSS-REFERENCE TO RELATED APPLICATION

The disclosure of Japanese Patent Application No. 2024-038804 filed on Mar. 13, 2024, including the specification, drawings and abstract is incorporated herein by reference in its entirety.

### BACKGROUND

The present disclosure relates to a semiconductor device and a method of manufacturing the semiconductor device.

There is disclosed a technique listed below.

[Patent Document 1] Japanese Unexamined Patent Application Publication No. 2020-120133

A semiconductor device described in the Patent Document 1 includes a semiconductor substrate, a trench gate electrode, a gate insulating film, an interlayer insulating film, an electrode pad, and a plating film. The semiconductor substrate has a first main surface and a second main surface opposite to the first main surface. A conductive type of the semiconductor substrate is an n-type. The semiconductor substrate serves as a drain region. An n-type source region positioned in the first main surface and a p-type region positioned between the source region and the drain region are formed in the semiconductor substrate. The p-type region is pn-bonded to the source region and the drain region.

A plurality of gate trenches and a plurality of trenches are formed on the second main surface. The gate trenches are arranged to be spaced apart from one another. The gate trenches extend toward the first main surface, penetrate the source region and the p-type region, and reach the drain region. Each of the trenches is formed between two adjacent gate trenches. The trenches extend toward the first main surface, penetrate the source region, and reach the p-type region.

A trench gate electrode is embedded in the gate trench. The gate insulating film is formed between side and bottom surfaces of the gate trench and the trench gate electrode. The interlayer insulating film is formed on the second main surface. A contact hole is formed in the interlayer insulating film. The contact hole penetrates the interlayer insulating film, and is connected to the trench. The electrode pad is formed on the interlayer insulating film. The electrode pad is embedded also in the contact hole and the trench, and thus, is electrically connected to the source region. The plating film is formed on the electrode pad. The plating film is formed by an electroless plating method.

### SUMMARY

In the semiconductor device described in the Patent Document 1, nodule may be formed on a surface of the plating film. Other problems and novel characteristics will be become apparent in the description of the present specification and the accompanying drawings.

A semiconductor device according to the present disclosure includes a semiconductor substrate, an interlayer insulating film, a first electrode pad and a second electrode pad, and a first plating film and a second plating film. The semiconductor substrate has a first main surface and a second main surface opposite to the first main surface. The second main surface includes a first region and a second region adjacent to the first region. The semiconductor substrate serves as an n-type drain region. The semiconductor substrate includes an n-type source region positioned in the first region, a p-type channel region adjacent to a side of the source region, the side being closer to the first main surface, and pn-bonded to the source region and the drain region, and a p-type well region positioned in the second region and pn-bonded to the drain region. The interlayer insulating film is formed on the second main surface. The first electrode pad and the second electrode pad are formed on the interlayer insulating film and are electrically connected to the source region and the well region, respectively. The first plating film and the second plating film are formed to cover the first electrode pad and the second electrode pad, respectively.

According to the semiconductor device of the present disclosure, the formation of the nodule on the surface of the first plating film can be prevented.

### BRIEF DESCRIPTIONS OF THE DRAWINGS

FIG. 1 is a plan view illustrating a semiconductor device DEV1.

FIG. 2 is a cross-sectional view taken along the line II-II of FIG. 1.

FIG. 3A is a first cross-sectional view illustrating the semiconductor device DEV1 connected to a connection member CM.

FIG. 3B is a second cross-sectional view illustrating the semiconductor device DEV1 connected to a connection member CM.

FIG. 4 is a diagram illustrating the steps of manufacturing the semiconductor device DEV1.

FIG. 5 is a cross-sectional view for explaining a trench forming step S2.

FIG. 6 is a cross-sectional view for explaining an insulating-film forming step S3.

FIG. 7 is a cross-sectional view for explaining a gate forming step S4.

FIG. 8 is a cross-sectional view for explaining an insulating-film forming step S5.

FIG. 9 is a cross-sectional view for explaining a gate forming step S6.

FIG. 10 is a cross-sectional view for explaining an ion implanting step S7.

FIG. 11 is a cross-sectional view for explaining an interlayer-insulating-film forming step S8.

FIG. 12 is a cross-sectional view for explaining a contact-hole forming step S9.

FIG. 13 is a cross-sectional view for explaining a trench forming step S10.

FIG. 14 is a cross-sectional view for explaining a contact-hole forming step S11.

FIG. 15 is a cross-sectional view for explaining a trench forming step S12.

FIG. 16 is a cross-sectional view for explaining an ion implanting step S13.

FIG. 17 is a cross-sectional view for explaining a contact-member forming step S14.

FIG. 18 is a cross-sectional view for explaining an electrode-pad forming step S15. FIG. 19 is a cross-sectional view for explaining a passivation-film forming step S16.

FIG. 20 is a cross-sectional view for explaining a plating-film forming step S17.

FIG. 21 is a cross-sectional view for explaining a polishing step S18.

FIG. 22 is a cross-sectional view for explaining an electrode forming step S19.

FIG. 23 is a cross-sectional view illustrating a semiconductor device DEV2.

FIG. 24 is a cross-sectional view illustrating a semiconductor device DEV3.

FIG. 25 is a cross-sectional view illustrating a semiconductor device DEV4.

FIG. 26 is a cross-sectional view illustrating the semiconductor device DEV4 according to a modification example.

### DETAILED DESCRIPTION

Embodiments of the present disclosure will be described in detail. In the following drawings, the same or corresponding components are denoted with the same reference signs, and the repetitive description thereof will not be repeated.

### First Embodiment

A semiconductor device according to a first embodiment will be described. The semiconductor device according to the first embodiment will be described as a semiconductor device DEV1.

### Configuration of Semiconductor Device DEV1

A configuration of the semiconductor device DEV1 will be described below.

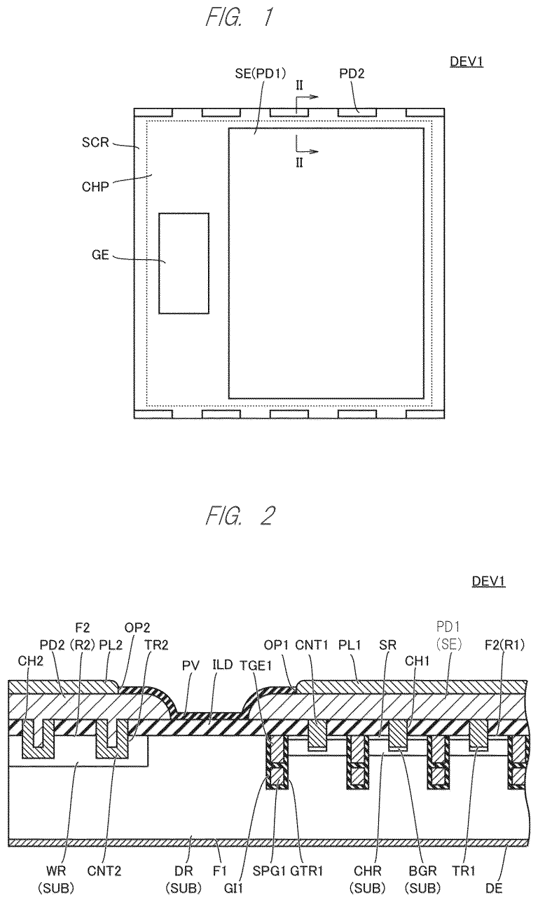

FIG. 1 is a plan view illustrating the semiconductor device DEV1. FIG. 2 is a cross-sectional view taken along the line II-II of FIG. 1. As illustrated in FIGS. 1 and 2, the semiconductor device DEV1 includes a semiconductor substrate SUB.

The semiconductor substrate SUB has a main surface F1 and a main surface F2. The main surface F2 is an opposite surface of the main surface F1. The main surface F1 and the main surface F2 are end surfaces of the semiconductor substrate SUB in the thickness direction. The main surface F2 includes a chip region CHP and a scribe region SCR. The scribe region SCR is along the outer periphery of the main surface F2 in plan view, and defines the chip region CHP. The main surface F2 includes a region R1 and a region R2. The region R1 and the region R2 are in, for example, the chip region CHP and the scribe region SCR, respectively.

A constituent material of the semiconductor substrate SUB is, for example, single crystal silicon. However, the constituent material of the semiconductor substrate SUB is not limited to this. The conductive type of the semiconductor substrate SUB is the n-type, and the semiconductor substrate SUB serves as a drain region DR. The drain region DR serves as the main surface F1. A source region SR, a channel region CHR, and a well region WR are formed in the semiconductor substrate SUB. A conductive type of the source region SR is an n-type. A conductive type of each of the channel region CHR and the well region WR is a p-type.

The source region SR is positioned in the region R1. The channel region CHR is adjacent to a side of the source region SR, the side being closer to the main surface F1. The well region WR is positioned in the region R2. The channel region CHR is pn-bonded to the source region SR and the drain region DR. The well region WR is pn-bonded to the drain region DR. The well region WR is formed deeper than the channel region CHR with reference to the main surface F2. That is, the bottom surface of the well region WR is farther away from the main surface F2 than the bottom surface of the channel region CHR.

A plurality of gate trenches GTR1 are formed in the region R1. The gate trenches GTR1 are arranged to be spaced apart from one another. The gate trenches GTR1 extend toward the main surface F1. The gate trenches GTR1 penetrate the source region SR and the channel region CHR, and reach the drain region DR. In other words, the bottom surfaces of the gate trenches GTR1 are positioned in the drain region DR.

A plurality of trenches TRI are formed in the region R1. The trench TR1 is arranged between two adjacent gate trenches

GTR1. The trenches TRI extend toward the main surface F1. The trenches TRI penetrate the source region SR, and reach the channel region CHR. That is, the bottom surfaces of the trenches TR1 are positioned in the channel region CHR. A backgate region BGR is further formed in the semiconductor substrate SUB. The backgate regions BGR are positioned at the bottom surfaces of the trench TR1. A conductive type of the backgate region BGR is a p-type.

A plurality of trenches TR2 are formed in the region R2. The trenches TR2 are arranged to be spaced apart from one another. The trenches TR2 extend toward the main surface F1. The trenches TR2 do not penetrate the well region WR. That is, the bottom surfaces of the trenches TR2 are positioned in the well region WR. The trenches TR2 are formed deeper than the trenches TR1 with reference to the main surface F2. That is, the bottom surfaces of the trenches TR2 are farther away from the main surface F2 than the bottom surfaces of the trenches TR1. The trenches TR2 are formed deeper than the channel region CHR with reference to the main surface F2. That is, the bottom surfaces of the trenches TR2 are farther away from the main surface F2 than the bottom surface of the channel region CHR. The trenches TR2 are used for optical critical dimension (OCD) using light. The trenches TR2 are used for, for example, measuring dimension at the time of the formation of the trenches TR1.

The semiconductor device DEV1 further includes a split gate SPG1 and a trench gate electrode TGE1. The split gate SPG1 and the trench gate electrode TGE1 are arranged in the gate trench GTR1. The trench gate electrode TGE1 is farther away from the bottom surface of the gate trench GTR1 than the split gate SPG1.

Each of a constituent material of the split gate SPG1 and a constituent material of the trench gate electrode TGE1 is, for example, dopant-containing polysilicon.

The semiconductor device DEVI further includes a gate insulating film GI1. The gate insulating film GI1 is arranged in the gate trenches GTR1, and individually surrounds each of the split gate SPG1 and the trench gate electrode TGE1. The trench gate electrode TGE1 faces the channel region CHR through the gate insulating film GI1. A constituent material of the gate insulating film GI1 is, for example, silicon oxide.

The semiconductor device DEV1 further includes an interlayer insulating film ILD. The interlayer insulating film ILD is formed on the main surface F2. A contact hole CH1 and a contact hole CH2 are formed in the interlayer insulating film ILD. The contact hole CH1 and the contact hole CH2 penetrate the interlayer insulating film ILD. The contact hole CH1 and the contact hole CH2 are arranged to respectively overlap the trench TR1 and the trench TR2 in plan view. That is, the contact hole CH1 is connected to the trench TR1, and the contact hole CH2 is connected to the trench TR2. A constituent t material of the interlayer insulating film ILD is, for example, silicon oxide.

The semiconductor device DEV1 further includes a contact member CNT1 and a contact member CNT2. The contact member CNT1 is embedded in the trench TR1 and the contact hole CH1. The contact member CNT1 is electrically connected to the source region SR and the backgate region BGR. The contact member CNT2 is embedded in the trench TR2 and the contact hole CH2. The contact member CNT2 is electrically connected to the well region WR.

Each of a constituent material of the contact member CNT1 and a constituent material of the contact member CNT2 is a conductor containing tungsten as a main component. A state in which a certain component is a main component means that a content of the component in the constituent material is 50 percent by mass or more.

The semiconductor device DEVI further includes an electrode pad PD1 and an electrode pad PD2. The electrode pad PD1 and the electrode pad PD2 are arranged on the interlayer insulating film ILD. More specifically, the electrode pad PD1 and the electrode pad PD2 are arranged above the region R1 and the region R2, respectively.

The electrode pad PD1 serves as a source electrode SE. The electrode pad PD1 is electrically connected to the contact member CNT1. That is, the electrode pad PD1 is electrically connected to the source region SR and the channel region CHR (backgate region BGR) via the contact member CNT1. The electrode pad PD2 is electrically connected to the contact member CNT2. That is, the electrode pad PD2 is electrically connected to the well region WR via the contact member CNT2. Each of a constituent material of the electrode pad PD1 and a constituent material of the electrode pad PD2 is, for example, a conductor containing aluminum as a main component.

The semiconductor device DEV1 further includes a gate electrode GE. The gate electrode GE is arranged on the interlayer insulating film ILD. Although not illustrated, the gate electrode GE is electrically connected to the trench gate electrode TGE1 via the contact member embedded in the contact hole formed in the interlayer insulating film ILD.

The semiconductor device DEV1 further includes a passivation film PV. The passivation film PV is formed on the interlayer insulating film ILD to cover the electrode pad PD1, the electrode pad PD2, and the gate electrode GE. An opening OP1 and an opening OP2 are formed in the passivation film PV. The opening OP1 and the opening OP2 penetrate the passivation film PV. The electrode pad PD1 and the electrode pad PD2 are exposed from the opening OP1 and the opening OP2. Although not illustrated, an opening for exposing the gate electrode GE is formed in the passivation film PV. A constituent material of the passivation film PV is silicon nitride.

The semiconductor device DEV1 further includes a plating film PL1 and a plating film PL2. The plating film PL1 is formed on the electrode pad PD1 exposed from the opening OP1. The plating film PL2 is formed on the electrode pad PD2 exposed from the opening OP2. The plating film PL1 and the plating film PL2 are plating films (electroless plating films) formed by, for example, an electroless plating method.

Each of the plating film PL1 and the plating film PL2 includes, for example, a first film, a second film, and a third film. The second film is formed on the first film. The third film is formed on the second film. A constituent material of the first film is, for example, a conductor containing nickel as a main component. A constituent material of the second film is, for example, a conductor containing palladium as a main component. A constituent material of the third film is, for example, a conductor containing gold as a main component. Although not illustrated, the semiconductor device DEV1 further includes a plating film similar to the plating film PL1 and the plating film PL2, which is formed on the gate electrode GE exposed from the opening of the passivation film PV.

The semiconductor device DEV1 further includes a drain electrode DE. The drain electrode DE is formed on the main surface F2. The drain electrode DE is electrically connected to the drain region DR. The drain electrode DE is a film (sputtering film) formed by, for example, a sputtering method. The drain electrode DE includes, for example, a first film, a second film, and a third film. The second film is formed on the first film.

The third film is formed on the second film. A constituent material of the first film is, for example, a conductor containing titanium as a main component. A constituent material of the second film is, for example, a conductor containing nickel as a main component. A constituent material of the third film is, for example, a conductor containing silver as a main component.

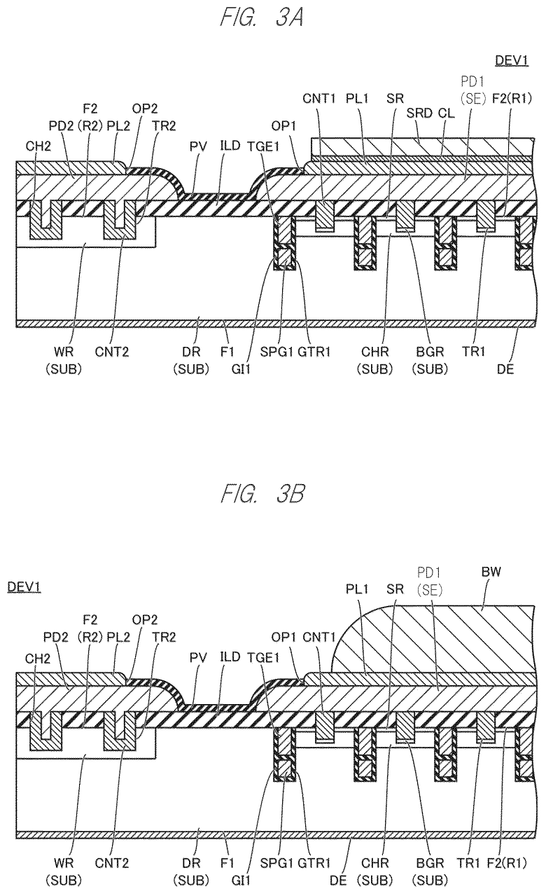

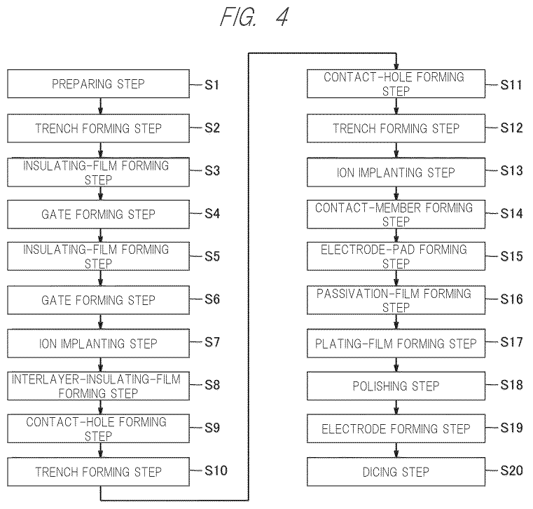

When a voltage is applied to the gate electrode GE, an inverted layer is formed in the channel region CHR facing the trench gate electrode TGE1 via the gate insulating film GI1, and the source region SR and the drain region DR are electrically connected. In this way, the source electrode SE (electrode pad PD1), the drain electrode DE, and the gate electrode GE configure a metal oxide semiconductor field effect transistor (MOSFET). FIG. 3A is a first cross-sectional view illustrating the semiconductor device DEV1 connected with a connection member CM. FIG. 3B is a second cross-sectional view illustrating the semiconductor device DEV1 connected with a connection member CM. As illustrated in FIGS. 3A and 3B, the connection member CM is connected to the plating film PL1. The connection member CM is made of, for example, a clip CL and solder SRD connecting the clip CL to the plating film PL1. The connection member CM may be a bonding wire BW.

### Method of Manufacturing Semiconductor Device DEV1

A method of manufacturing the semiconductor device DEV1 will be described below.

FIG. 4 is a diagram illustrating the steps of manufacturing the semiconductor device DEV1. As illustrated in FIG. 4, the method of manufacturing the semiconductor device DEV1 includes a preparing step S1, a trench forming step S2, an insulating-film forming step S3, a gate forming step S4, an insulating-film forming step S5, a gate forming step S6, an ion implanting step

S7, an interlayer-insulating-film forming step S8, a contact-hole forming step S9, a trench forming step S10, a contact-hole forming step S11, and a trench forming step S12. The method of manufacturing the semiconductor device DEVI further includes an ion implanting step S13, a contact-member forming step S14, an electrode-pad forming step S15, a passivation-film forming step S16, a plating-film forming step S17, a polishing step S18, an electrode forming step S19, and a dicing step S20.

In the preparing step S1, the semiconductor substrate SUB is prepared. The source region SR, the channel region CHR, the well region WR, and the backgate region BGR are not formed in the semiconductor substrate SUB prepared in the preparing step S1.

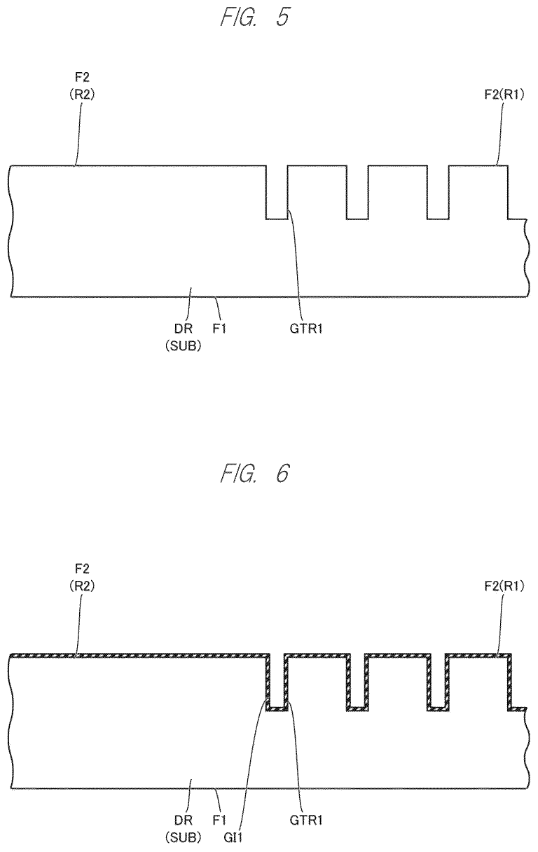

FIG. 5 is a cross-sectional view for explaining the trench forming step S2. As illustrated in FIG. 5, in the trench forming step S2, the main surface F2 is etched to form the gate trench GTR1 in the main surface F2. FIG. 6 is a cross-sectional view for explaining the insulating-film forming step As S3. illustrated in FIG. 6, in the insulating-film forming step S3, the gate insulating film GIL is formed on the side and bottom surfaces of the gate trench GTR1 by, for example, thermal oxidation.

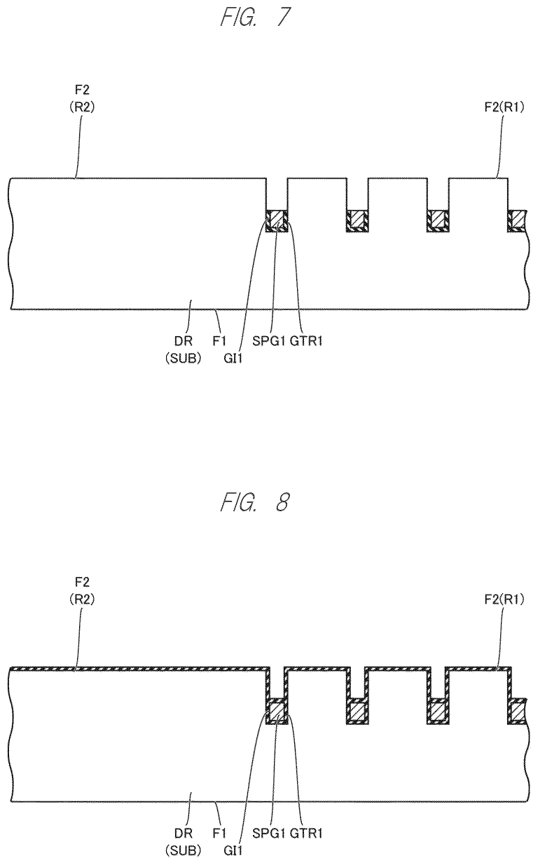

FIG. 7 is a cross-sectional view for explaining the gate forming step S4. As illustrated in FIG. 7, in the gate forming step S4, the split gate SPG1 is embedded in the gate trench GTR1. The split gate SPG1 is formed by forming the constituent material of the split gate SPG1 by, for example, a chemical vapor deposition (CVD) method, and then, partially removing the formed constituent material of the split gate SPG1 by a chemical mechanical polishing (CMP) method or an etch-back method.

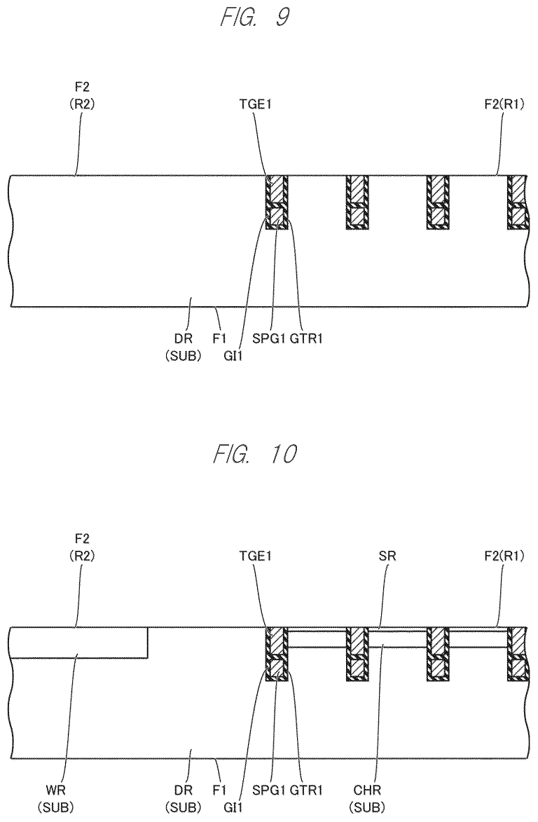

FIG. 8 is a cross-sectional view for explaining the insulating-film forming step S5. As illustrated in FIG. 8, in the insulating-film forming step S5, the gate insulating film GI1 is further formed to cover the split gate SPG1 by, for example, a CVD method. FIG. 9 is a cross-sectional view for explaining the gate forming step S6. As illustrated in FIG. 9, in the gate forming step S6, the trench gate electrode TGE1 is embedded in the gate trench GTR1. The trench gate electrode TGE1 is formed by forming the constituent material of the trench gate electrode TGE1 by, for example, a CVD method, and then, partially removing the formed constituent material of the trench gate electrode TGE1 by a CMP method or an etch-back method. FIG. 10 is a cross-sectional view for explaining the ion implanting step S7. As illustrated in FIG. 10, in the ion implanting step S7, ion is implanted to form the source region SR, the channel region CHR, and the well region WR.

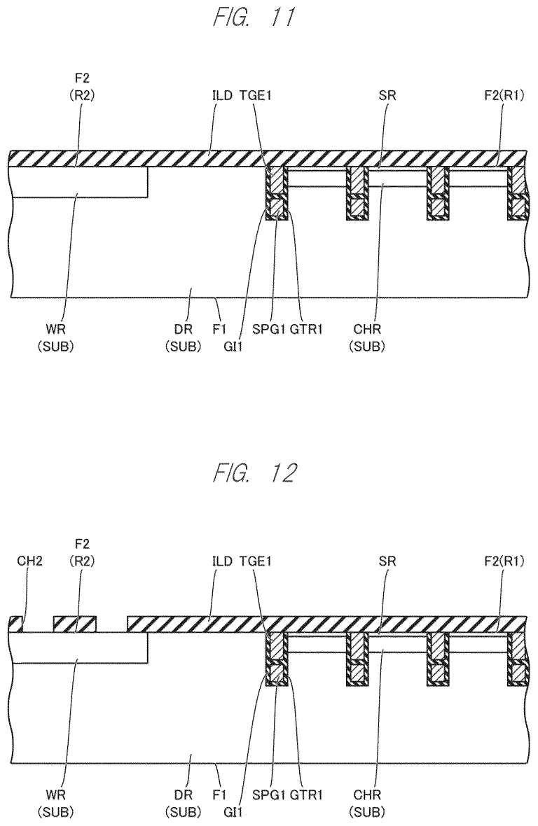

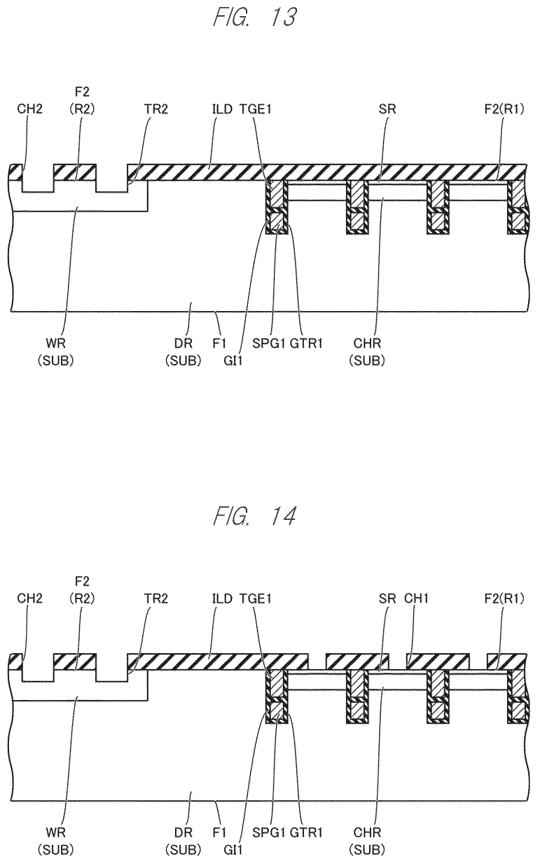

FIG. 11 is a cross-sectional view for explaining the interlayer-insulating-film forming step S8. As illustrated in FIG. 11, in the interlayer-insulating-film forming step S8, the interlayer insulating film ILD is formed by, for example, a CVD method. FIG. 12 is a cross-sectional view for explaining the contact hole forming step S9. As illustrated in FIG. 12, in the contact-hole forming step S9, the interlayer insulating film ILD is etched to form the contact hole CH2. FIG. 13 is a cross-sectional view for explaining the trench forming step S10. As illustrated in FIG. 13, in the trench forming step S10, the main surface F2 is etched while using the interlayer insulating film ILD as a mask to form the trench TR2.

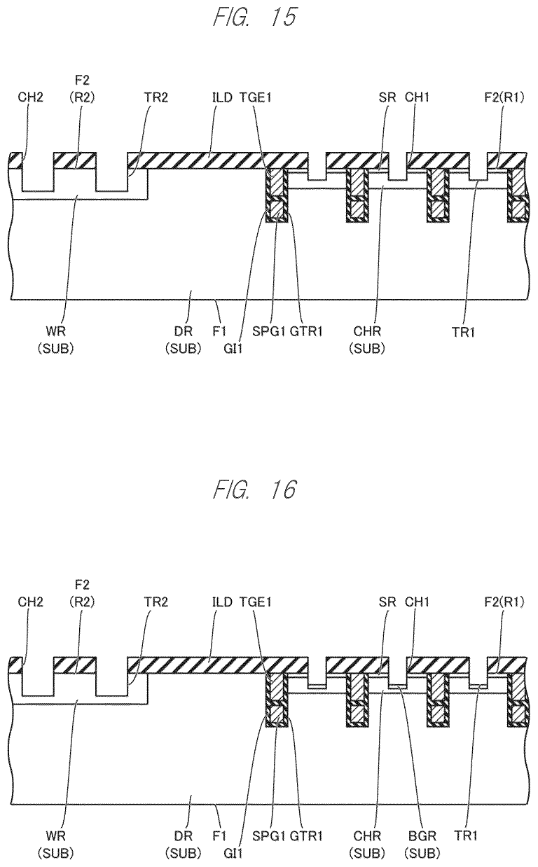

FIG. 14 is a cross-sectional view for explaining the contact-hole forming step S11. As illustrated in FIG. 14, in the contact-hole forming step S11, the interlayer insulating film ILD is etched to form the contact hole CH1. FIG. 15 is a cross-sectional view for explaining the trench forming step S12. As illustrated in FIG. 15, in the trench forming step S12, the main surface F2 is etched while using the interlayer insulating film ILD as a mask to form the trench TR1. The trench TR2 is made deeper by the etching at this time, and consequently the trench TR2 is formed deeper than the trench TR1.

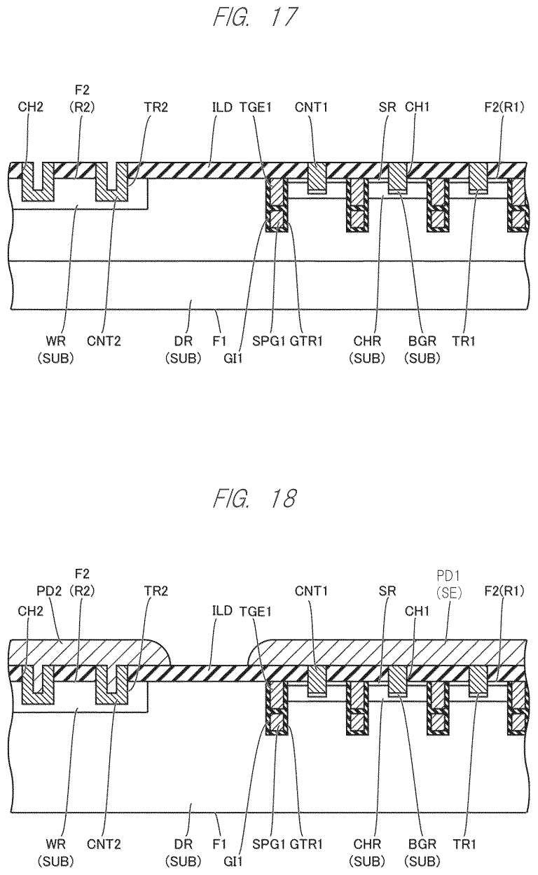

FIG. 16 is a cross-sectional view for explaining the ion implanting step S13. As illustrated in FIG. 16, in the ion implanting step S13, the backgate region BGR is formed via the contact hole CH1 by ion implantation. FIG. 17 is a cross-sectional view for explaining the contact-member forming step S14. As illustrated in FIG. 17, in the contact-member forming step S14, the contact member CNT1 is embedded in the contact hole CH1 and the trench TR1, and the contact member CNT2 is embedded in the contact hole CH2 and the trench TR2. Each of the contact member CNT1 and the contact member CNT2 is formed by forming its constituent material by, for example, a CVD method, and then, partially removing the formed constituent material by a CMP method or the like.

FIG. 18 is a cross-sectional view for explaining the electrode-pad forming step S15. As illustrated in FIG. 18, in the electrode-pad forming step S15, the electrode pad PD1 (source electrode SE) and the electrode pad PD2 are formed on the interlayer insulating film ILD. Each of the electrode pad PD1 and the electrode pad PD2 is formed by forming its constituent material on the interlayer insulating film ILD by sputtering or the like, and then, etching and patterning the formed constituent material while using a mask formed by photolithography. Although not illustrated, the gate electrode GE is also formed in this step.

FIG. 19 is a cross-sectional view for explaining the passivation-film forming step S16. As illustrated in FIG. 19, in the passivation-film forming step S16, the passivation film PV is formed on the interlayer insulating film ILD to cover the electrode pad PD1, the electrode pad PD2, and the gate electrode GE. The passivation film PV is formed by forming a constituent material of the passivation film PV, and then, etching and patterning the formed constituent material while using a mask formed by photolithography.

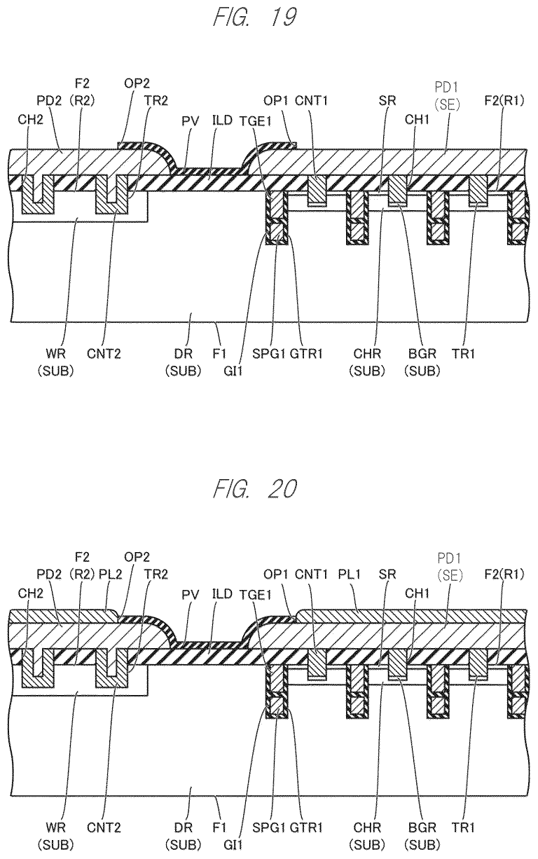

FIG. 20 is a cross-sectional view for explaining the plating-film forming step S17. As illustrated in FIG. 20, in the plating-film forming step S17, the plating film PL1 and the plating film PL2 are formed. The plating film PL1 and the plating film PL2 are formed by performing, for example, a zincate processing and then electroless plating on the surface of the electrode pad PD1 and the surface of the electrode pad PD2. The zincate processing may be performed, for example, plural times. At this time, although not illustrated, a plating film is also formed on the gate electrode GE.

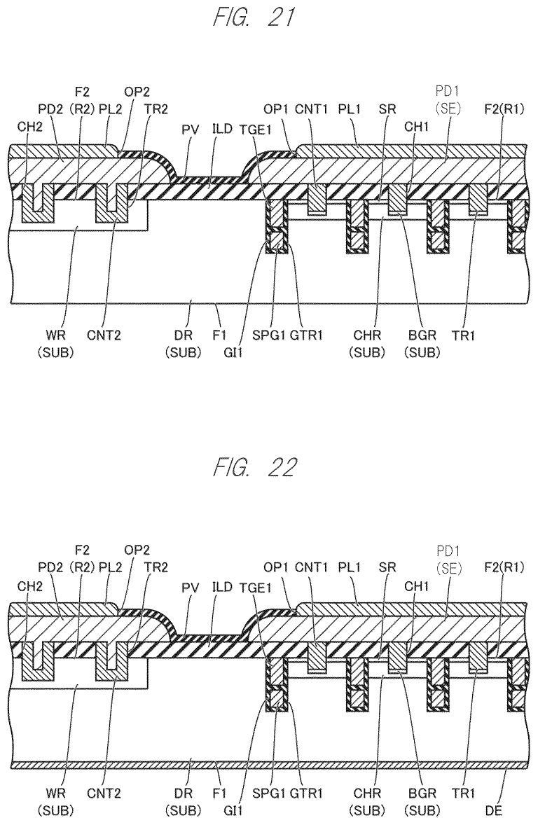

FIG. 21 is a cross-sectional view for explaining the polishing step S18. As illustrated in FIG. 21, in the polishing step S18, the main surface F1 is polished. Thereby, the thickness of the semiconductor substrate SUB decreases. FIG. 22 is a cross-sectional view for explaining the electrode forming step S19. As illustrated in FIG. 22, in the electrode forming step S19, the drain electrode DE is formed on the main surface F1 by, for example, a sputtering method.

In the dicing step S20, the semiconductor wafer is diced into a plurality of semiconductor devices DEV1 by dicing along the scribe region SCR. The structure of the semiconductor device DEV1 illustrated in FIGS. 1 and 2 is formed by the above-described steps.

### Effects of Semiconductor Device DEV1

Effects of the semiconductor device DEV1 will be described below.

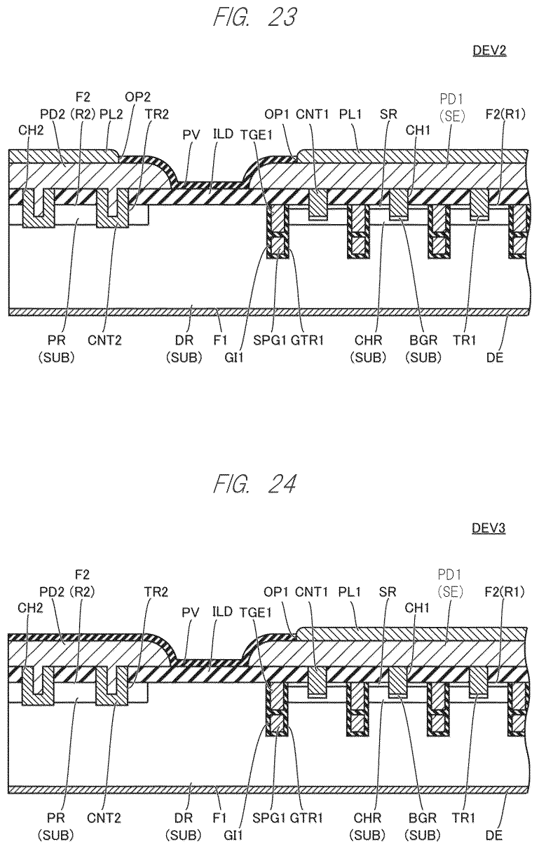

A semiconductor device according to a comparative example is assumed as semiconductor device DEV2. FIG. 23 is a cross-sectional view illustrating the semiconductor device DEV2. As illustrated in FIG. 23, in the semiconductor device DEV2, a p-type region PR is formed in the region R2, instead of the well region WR. The p-type region PR is formed not to be deeper than the channel region CHR. Since the trench TR2 is formed to be deeper than the channel region CHR, the trench TR2 in the semiconductor device DEV2 penetrates the p-type region PR, and reaches the drain region DR. Consequently, in the semiconductor device DEV2, the electrode pad PD2 is electrically connected to the drain region DR via the contact member CNT2.

The zincate processing of the plating-film forming step S17 causes a reaction of “Al+3OH⁻→Al(OH)₃+3e⁻” and a reaction of “Zn²⁺2e⁻∵Zn”. Since the electrode pad PD2 in the semiconductor device DEV2 is electrically connected to the semiconductor substrate SUB, the reactions are easily advanced on the surface of the electrode pad PD2, and aluminum excessively dissolves on the surface of the electrode pad PD2. Such excessive aluminum dissolution becomes a cause of occurrence of the nodule on the plating film PL1 formed on the electrode pad PD1 at the downstream side of the electrode pad PD2 in a direction of a flow of a plating solution. The nodule becomes a cause of failure in appearance or failure in connection with the connection member CM.

To the contrary, in the semiconductor device DEV1, the well region WR is pn-bonded to the drain region DR, and the trench TR2 does not penetrate the well region WR, and thus, the electrode pad PD2 is not electrically connected to the semiconductor substrate SUB (drain region DR). Therefore, exchange of electrons between the electrode pad DP2 and the semiconductor substrate SUB is limited, and the excessive aluminum dissolution during the zincate processing is prevented. As described above, according to the semiconductor device DEV1, the occurrence of the nodule on the plating film PL1 can be prevented.

### Second Embodiment

A semiconductor device according to a second embodiment will be described. The semiconductor device according to the second embodiment is assumed as a semiconductor device DEV3. Differences from the semiconductor device DEV1 will be mainly described, and the overlapping description thereof will not be repeated.

### Configuration of Semiconductor Device DEV3

A configuration of the semiconductor device DEV3 will be described below.

FIG. 24 cross-sectional is a view illustrating the semiconductor device DEV3. As illustrated in FIG. 24, in the semiconductor device DEV3, the p-type region PR is formed in the region R2, instead of the well region WR, and the trench TR2 penetrates the channel region CHR. That is, in the semiconductor device DEV3, the electrode pad PD2 is electrically connected to the semiconductor substrate SUB (drain region DR) via the contact member CNT2.

In the semiconductor device DEV3, the opening OP2 is not formed in the passivation film PV, and the electrode pad PD2 is not exposed from the passivation film PV. That is, the semiconductor device DEV3 does not include the plating film PL2. The configuration of the semiconductor device DEV3 is different from the configuration of the semiconductor device DEV1 in the points.

### Method of Manufacturing Semiconductor Device DEV3

A method of manufacturing the semiconductor device DEV3 will be described below.

In the method of manufacturing the semiconductor device DEV3, in the ion implanting step S7, ion is implanted into the region R2 as similar to the region R1, and the p-type region PR is formed in the region R2, instead of the well region WR. Further, in the method of manufacturing the semiconductor device DEV3, the opening OP2 is not formed in the passivation-film forming step S16, and the plating film PL2 is not formed in the plating-film forming step S17. The method of manufacturing the semiconductor device DEV3 is different from the method of manufacturing the semiconductor device DEV1 in the points.

### Effects of Semiconductor Device DEV3

Effects of the semiconductor device DEV3 will be described below. In the semiconductor device DEV3, the opening OP2 is not formed by the passivation-film forming step S16, and the surface of the electrode pad PD2 is covered with the passivation film PV during the zincate processing by the plating-film forming step S17. Therefore, according to the semiconductor device DEV3, the excessive aluminum dissolution is difficult to be caused on the surface of the electrode pad PD2, and accordingly the nodule is difficult to occur on the surface of the plating film PL1.

### Third Embodiment

A semiconductor device according to a third embodiment will be described. The semiconductor device according to the third embodiment is assumed as a semiconductor device DEV4. Differences from the semiconductor device DEV1 will be mainly described, and the overlapping description thereof will not be repeated.

### Configuration of Semiconductor Device DEV4

A configuration of the semiconductor device DEV4 will be described below.

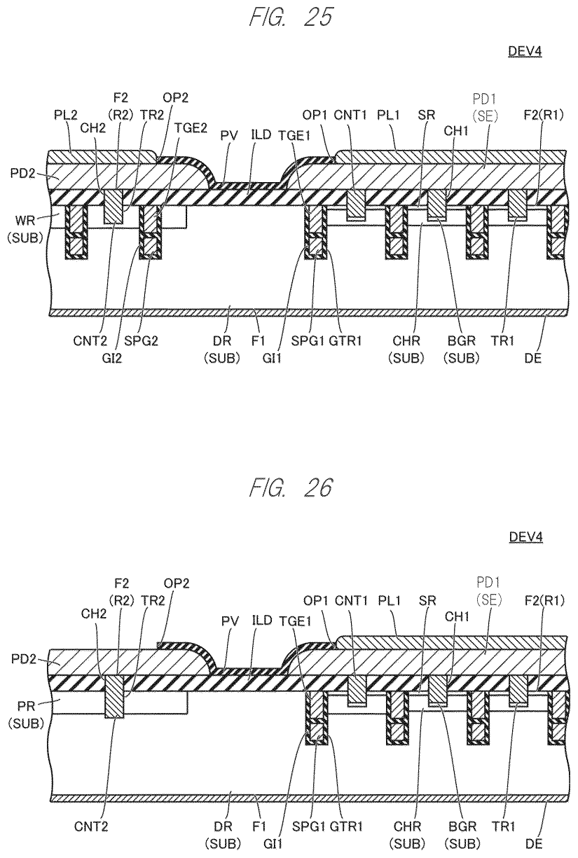

FIG. 25 is a cross-sectional view illustrating the semiconductor device DEV4. As illustrated in FIG. 25, in the semiconductor device DEV4, the region R2 where the well region WR is formed is positioned in the chip region CHP. In the semiconductor device DEV4, a plurality of gate trenches GTR2 are formed in the region R2. A split gate SPG2 and a trench gate electrode TGE2 are embedded in a gate trench GTR2. Each of the split gate SPG2 and the trench gate electrode TGE2 is surrounded by a gate insulating film GI2 in the gate trench GTR2. The trench gate electrode TGE2 is positioned to be higher than the split gate SPG2, and faces the well region WR via the gate insulating film GI2.

In the semiconductor device DEV4, the electrode pad PD2 serves as an electrode pad for inspection. That is, in the semiconductor device DEV4, a voltage is applied to the trench gate electrode TGE1 and the tranche gate electrode TGE2 to electrically connect the channel region CHR and the drain region DR and to electrically connect the well region WR and the drain region DR, and thus, a current flows between the electrode pad PD1 and the electrode pad PD2 via the drain region DR. Thereby, the property of the MOSFET can evaluated. The configuration of the semiconductor device DEV4 is different from the configuration of the semiconductor device DEV1 in the points.

### Method of Manufacturing Semiconductor Device DEV4

A method of manufacturing the semiconductor device DEV4 will be described below.

In the method of manufacturing the semiconductor device DEV4, by the trench forming step S2, the gate trench GTR2 is also formed in addition to the gate trench GTR1. In the method of manufacturing the semiconductor device DEV4, by the insulating-film forming step S3, the gate forming step S4, the insulating-film forming step S5, and the gate forming step S6, the gate insulating film GI2, the split gate SPG2, and the trench gate electrode TGE2 are also formed in addition to the gate insulating film GI1, the split gate SPG1, and the trench gate electrode TGE1. The method of manufacturing the semiconductor device DEV4 is different from the method of manufacturing the semiconductor device DEV1 in the points.

### Effects of Semiconductor Device DEV4

Effects of the semiconductor device DEV4 will be described below.

Since a voltage is not applied to the trench gate electrode TGE2 during the plating-film forming step S17, the electrode pad PD2 is not electrically connected to the semiconductor substrate SUB due to the pn junction between the well region WR and the drain region DR, the exchange of electrons between the electrode pad PD2 and the semiconductor substrate SUB is limited, thereby preventing the excessive aluminum dissolution on the surface of the electrode pad PD2 during the zincate processing, and consequently preventing the occurrence of the nodule on the surface of the plating film PL1.

To the contrary, a voltage is applied to the trench gate electrode TGE2 at the time of the inspection of the semiconductor device DEV4, and thus, a current flows between the electrode pad PD2 and the electrode pad PD1 via the drain region DR, and thus, the electrode pad PD2 serves as the electrode pad for inspection. As described above, according to the semiconductor device DEV4, the occurrence of the nodule on the surface of the plating film PL1 can be prevented, and the electrode pad PD2 can be electrically functioned.

### Modification Example

FIG. 26 is a cross-sectional view illustrating the semiconductor device DEV4 according to a modification example. As illustrated in FIG. 26, in the semiconductor device DEV4, the p-type region PR is formed instead of the well region WR, and the trench TR2 may penetrate the p-type region PR and reach the drain region DR. In this case, the electrode pad PD1 is electrically connected to the semiconductor substrate SUB (drain region DR) via the contact member CNT2.

Additionally, in this case, the gate trench GTR2 is not formed in the region R2, and the semiconductor device DEV4 does not include the gate insulating film GI2, the split gate SPG2, the trench gate electrode TGE2, and the plating film PL2. In this case, the opening OP2 is not formed in the passivation film PV by the passivation-film forming step S16. Consequently, the surface of the electrode pad PD2 is covered with the passivation film PV during the zincate processing, and the excessive aluminum dissolution on the electrode pad PD2 is prevented. However, in this case, in order to function the electrode pad PD2 as the electrode pad for inspection, etching for forming the opening OP2 in the passivation film PV is additionally performed after the plating-film forming step S17.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a semiconductor substrate;
an interlayer insulating film;
a first electrode pad and a second electrode pad; and
a first plating film and a second plating film,
wherein the semiconductor substrate has a first main surface and a second main surface opposite to the first main surface,
wherein the second main surface includes a first region and a second region adjacent to the first region,
wherein the semiconductor substrate serves as an n-type drain region,
wherein the semiconductor substrate includes:
an n-type source region positioned in the first region;
a p-type channel region adjacent to a side of the source region, the side being closer to the first main surface, and pn-bonded to the source region and the drain region; and
a p-type well region positioned in the second region and pn-bonded to the drain region,
wherein the interlayer insulating film is formed on the second main surface,
wherein the first electrode pad and the second electrode pad are formed on the interlayer insulating film and are electrically connected to the source region and the well region, respectively, and
wherein the first plating film and the second plating film are formed to cover the first electrode pad and the second electrode pad, respectively.

2. The semiconductor device according to claim 1, further comprising:
a first contact member and a second contact member,
wherein a first trench is formed in the first region to reach the channel region,
wherein a second trench is formed in the second region to reach the well region,
wherein the first contact member and the second contact member are embedded in the first trench and the second trench, respectively,
wherein the first electrode pad is electrically connected to the source region via the first contact member, and
wherein the second electrode pad is electrically connected to the well region via the second contact member.

3. The semiconductor device according to claim 2,
wherein the well region is formed to be deeper than the channel region with reference to the second main surface, and
wherein a bottom surface of the second trench is positioned in the well region.

4. The semiconductor device according to claim 1,
wherein the second electrode pad is an electrode pad for inspection configured to make a flow of a current between the second electrode pad and the first electrode pad via the drain region.

5. The semiconductor device according to claim 2,
wherein a plurality of second trenches are formed to be spaced apart from one another and be a pattern for measuring a dimension while using light.

6. The semiconductor device according to claim 5,
wherein the second main surface includes a chip region and a scribe region defining the chip region, and
wherein the first region and the second region are positioned in the chip region and the scribe region, respectively.

7. The semiconductor device according to claim 2,
wherein each of the first electrode pad and the second electrode pad is made of a conductor containing aluminum as a main component,
wherein each of the first contact member and the second contact member is made of a conductor containing tungsten as a main component,
wherein each of the first plating film and the second plating film includes a first film made of a conductor containing nickel as a main component, a second film made of a conductor containing palladium as a main component, and a third film made of a conductor containing gold as a main component.

8. The semiconductor device according to claim 1,
wherein the first plating film and the second plating film are formed by an electroless plating method.

9. The semiconductor device according to claim 1, further comprising:
A connection member,
wherein the connection member is made of a bonding wire or a clip connected to the first plating film, and solder connecting the clip to the first plating film.

10. The semiconductor device according to claim 1, further comprising:
a trench gate electrode;
a gate electrode; and
a drain electrode,
wherein a gate trench penetrating the source region and the channel region and reaching the drain region is formed in the first region,
wherein the trench gate electrode is embedded in the gate trench,
wherein the gate electrode is formed on the interlayer insulating film,
wherein the first electrode pad serves source electrode,
wherein the drain electrode is formed on the first main surface, and
wherein the source electrode, the gate electrode, and the drain electrode configure a MOSFET.

11. A semiconductor device comprising:
a semiconductor substrate;
an interlayer insulating film;
a first electrode pad and a second electrode pad;
a passivation film; and
a first plating film,
wherein the semiconductor substrate has a first main surface and a second main surface opposite to the first main surface,
wherein the second main surface includes a first region and a second region adjacent to the first region,
wherein the semiconductor substrate serves as an n-type drain region,
wherein the semiconductor substrate includes:
an n-type source region positioned in the first region; and
a p-type channel region adjacent to a side of the source region, the side being closer to the first main surface, and pn-bonded to the source region and the drain region,
wherein the interlayer insulating film is formed on the second main surface,
wherein the first electrode pad and the second electrode pad are formed on the interlayer insulating film and are electrically connected to the source region and the drain region, respectively,
wherein the passivation film is formed to cover the first electrode pad and the second electrode pad, and includes an opening formed therein, configured to expose part of the first electrode pad,
wherein the first plating film is formed on the first electrode pad exposed from the opening, and
wherein the first plating film is not formed on the first electrode pad.

12. The semiconductor device according to claim 11, further comprising:
a first contact member and a second contact member,
wherein a first trench is formed in the first region to reach the channel region,
wherein a second trench is formed in the second region to reach the drain region,
wherein the first contact member and the second contact member are embedded in the first trench and the second trench, respectively,
wherein the first electrode pad is electrically connected to the source region via the first contact member, and
wherein the second electrode pad is electrically connected to the drain region via the second contact member.

13. The semiconductor device according to claim 12,
wherein a plurality of second trenches are formed to be spaced apart from one another and be a pattern for measuring a dimension while using light.

14. The semiconductor device according to claim 11,
wherein the second main surface includes a chip region and a scribe region defining the chip region, and
wherein the first region and the second region are positioned in the chip region and the scribe region, respectively.

15. The semiconductor device according to claim 12,
wherein each of the first electrode pad and the second electrode pad is made of a conductor containing aluminum as a main component,
wherein each of the first contact member and the second contact member are made of a conductor containing tungsten as a main component, and
wherein the first plating film includes a first film made of a conductor containing nickel as a main component, a second film made of a conductor containing palladium as a main component, and a third film made of a conductor containing gold as a main component.

16. The semiconductor device according to claim 11,
wherein the first plating film is formed by an electroless plating method.

17. The semiconductor device according to claim 11, further comprising:
A connection member,
wherein the connection member is made of a bonding wire or a clip connected to the first plating film, and solder connecting the clip to the first plating film.

18. The semiconductor device according to claim 11, further comprising:
a trench gate electrode;
a gate electrode; and
a drain electrode,
wherein a gate trench penetrating the source region and the channel region and reaching the drain region is formed in the first region,
wherein the trench gate electrode is embedded in the gate trench,
wherein the gate electrode is formed on the interlayer insulating film,
wherein the first electrode pad serves as a source electrode,
wherein the drain electrode is formed on the first main surface, and
wherein the source electrode, the gate electrode, and the drain electrode configure a MOSFET.

19. A method of manufacturing a semiconductor device, comprising steps of:
preparing a semiconductor substrate;
wherein the semiconductor substrate has a first main surface and a second main surface opposite to the first main surface,
wherein the second main surface includes a first region and a second region adjacent to the first region,
wherein the semiconductor substrate serves as an n-type drain region, and
wherein the semiconductor substrate includes:
an n-type source region positioned in the first region;
a p-type channel region adjacent to a side of the source region, the side being closer to the first main surface, and pn-bonded to the source region and the drain region; and
a p-type well region positioned in the second region and pn-bonded to the drain region,
the method further comprising steps of:
forming an interlayer insulating film on the second main surface;
forming, on the interlayer insulating film, a first electrode pad and a second electrode pad electrically connected to the source region and the well region, respectively; and
forming a first plating film and a second plating film to cover the first electrode pad and the second electrode pad, respectively.
